(19) United States
(12) Patent Application Publication
(10) Pub. No.: US 2010/0327364 A1
(43) Pub. Date: Dec. 30, 2010

(54) SEMICONDUCTOR DEVICE WITH METAL GATE

(75) Inventor: Yoshinori Tsuchiya, Clifton Park, NY (US)

Correspondence Address: TUROCY & WATSON, LLP, 127 Public Square, 57th Floor, Key Tower, CLEVELAND, OH, 44114, US

(73) Assignee: TOSHIBA AMERICA ELECTRONIC COMPONENTS, INC., Irvine, CA (US)

(21) Appl. No.: 12/493,474

(22) Filed: Jun. 29, 2009

(51) Int. Cl. H01L 27/092; H01L 29/49; H01L 21/336

(52) U.S. Cl. 257/369; 257/412; 438/197; 257/E27.062; 257/E29.16; 257/E21.409

(57) ABSTRACT

A semiconductor device includes: a substrate and an n-channel MIS transistor. The n-channel MIS transistor includes a p-type semiconductor region formed on the substrate, wherein a first source/drain region is formed in the p-type semiconductor region and separated from each other. The n-channel MIS transistor includes a first gate insulating film on the p-type semiconductor region between the first source/drain regions. The n-channel MIS transistor further includes a first gate electrode having a stack structure formed with a gate dielectric, a first metal layer and a first compound layer, the first metal layer having a thickness less than 2 nm and having a work function of 4.3 eV or smaller, the first metal layer being formed on the metallic layer having a work function larger than 4.4 eV and the first compound layer containing Al and a second metal that is different from the first metal.

### TECHNICAL FIELD

The present invention relates to a semiconductor device having MISFETs and a method for manufacturing the semiconductor device.

### BACKGROUND

“Silicon large-scale integrated circuit” is one of the fundamental device technologies that will support the advanced information society in the future. To produce an integrated circuit with highly sophisticated functions, it is necessary to prepare semiconductor devices that yield high performances, such as MOSFETs (Metal-Oxide-Semiconductor Field Effect Transistors) or CMOSFETs (Complementary MOSFETs) that can constitute an integrated circuit. The performances of devices have been improved basically in accordance with the scaling rule. In recent years, however, it has been difficult to achieve high performances by making devices smaller, due to various physical limitations.

With gate electrodes formed with silicon, there have been such problems as the increasing gate parasitic resistance observed with the higher device operation speed, the decreases of the effective capacitances of insulating films due to the carrier depletion at the interfaces with the insulating films, and the variations in threshold voltage due to the added impurities spreading into the channel regions. To solve those problems, metal gate materials have been suggested.

One of the metal gate electrode forming techniques is a fully-silicided gate electrode technique by which all the gate electrodes are silicided with Ni or Co. To achieve a device operation with an optimum operational threshold voltage, the metal gate electrodes need to have different work functions according to the conductivity types as well as target Vt values.

This is because the operational threshold voltage of each MIS transistor is modulated with the variation of the gate electrode work function (the effective work function (Φeff)) at the interface between the gate electrode and the gate insulating film. The formation of the gate electrodes having the respective optimum work functions according to the conductivity types complicates the production process of the CMOSFET, and increases the production costs. Therefore, methods for controlling the work function of each electrode through simple procedures are being developed. Typical techniques for controlling the work functions of each electrode include complicated and costly procedures.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Rather, the sole purpose of this summary is to present some concepts of the invention in a simplified form as a prelude to the more detailed description that is presented hereinafter.

One aspect of the subject innovation relates to a semiconductor device structure that can reduce contact resistance in the gate electrode. The semiconductor device can include a substrate and an n-channel MIS transistor. The n-channel MIS transistor can include a p-type semiconductor region formed on the substrate and a first source region and a first drain region, wherein the first source/drain regions are formed in the p-type semiconductor region and being separated from each other. The n-channel MIS transistor can further include a first gate insulating film on the p-type semiconductor region between the first source/drain region. The n-channel MIS transistor can further include a first gate electrode having a stack formed with a first metal layer, a first compound layer and a NiSi layer which contains Al. The first metal layer can have a thickness less than 2 nm and a work function of 4.3 eV or smaller, wherein the first metal layer being formed on the metallic layer has a work function larger than 4.4 eV and the first compound layer contains Al and a second metal that is different from the first metal.

Another aspect of the subject innovation relates to a device structure with an NFET and a PFET CMOS that can reduce contact resistance at the gate electrode/gate dielectric interface. The device structure can include a PFET that has a first gate electrode having a stack structure formed with a metallic layer contact gate dielectric and a first metal layer, the first compound layer being formed on the metallic layer having a work function larger than 4.4 eV.

Yet another aspect of the innovation relates to a device structure with a high-Vt nMOS and a low-Vt nMOS. The device structure can include a rare-earth metal oxide-capped gate dielectric in the low-Vt nMOS. Moreover, the a first gate electrode in the n-type channel MIS transistor and the first gate electrode in the second n-type channel MIS transistor can have a stack structure formed with a metallic Al layer contact gate dielectric, a first metal layer and a first compound layer.

In still another aspect of the innovation, a device structure is described that utilizes three (3) Vt for an nMOS (e.g., NFET), a midgap (e.g., high-Vt-PFET), and a pMOS (e.g., Low-Vt-PFET). The device structure can include an n-channel MIS transistor, a first p-type channel MIS transistor, and a second p-type channel MIS transistor. The n-channel MIS transistor can have a stack structure formed with a metallic layer contact gate dielectric, and a first compound layer. The first p-type channel MIS transistor can have a first gate electrode having a stack structure formed with a metallic layer contact gate dielectric and a first metal layer. The second p-type channel MIS transistor can include an oxidized layer contact gate dielectric, a first compound layer, and a metallic Al layer.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF SUMMARY OF THE DRAWINGS

FIG. 1 is a cross-sectional view of a CMISFET in accordance with an aspect of the invention.

FIG. 2 is a cross-sectional view of a CMISFET in accordance with an aspect of the invention.

FIG. 3 is a cross-sectional view of a CMISFET in accordance with an aspect of the invention.

FIG. 4 is a cross-sectional view of a CMISFET in accordance with an aspect of the invention.

FIG. 5 is a methodology with schematic views illustrating the procedures for forming a CMISFET in accordance with an aspect of the invention.

### DETAILED DESCRIPTION

The following is a description of embodiments of the subject innovation, with reference to the accompanying drawings. The accompanying drawings are schematic views designed to facilitate explanation and understanding of the innovation. The shapes, sizes, and ratios shown in the drawings might be different from those of the actual devices, but they may be arbitrarily changed or modified, with the following description and the conventional techniques being taken into account.

In each of the following embodiments, MIS transistors or CMIS transistors will be described. However, the subject innovation may be applied to system LSI and the likes that include logic circuits and some other circuits having MIS transistors integrated thereon.

In a reference (Chang Seo Park et al., “Dual Metal Gate Process by Metal Substitution of Dopant-Free Polysilicon on High-K Dielectric,” 2005 Symposium on VLSI Technology Digest of Technical Papers), an Al substation to poly-Si gate is described to adjust Vt in nMOS. However, this method can deteriorate the reliability of the transistor due to mechanical stress and penetration to the channel of the Al gate during BEOL process. Moreover, a reference (P. Sivasubramani et al., “Dipole Moment Model Explaining nFET Vt Tuning Utilizing La, Sc, Er, and Sr Doped HfSiON Dielectrics,” 2007 Symposium on VLSI Technology Digest of Technical Papers) describes rare-earth metal insertion to HK/I.L interface to control nMOSFET Vt. However, such method can deteriorate the transistor performance and reliability due to fixed charge generation in the HK layer.

The subject innovation mitigates the above mentioned deficiencies with a gate electrode that consists of a bottom-metal layer and a top metallic layer containing Si with having Al-contained interfacial layer at the gate electrode/gate dielectric interface. By doing so, a work function, which is suitable for an n-type MOS metal on a gate insulating film, is achieved with a simplified procedure. In addition, a semiconductor device performance and reliability is improved based upon such device does not have a complicated film removing process and re-exposing of gate-dielectric surface or Si-channel region.

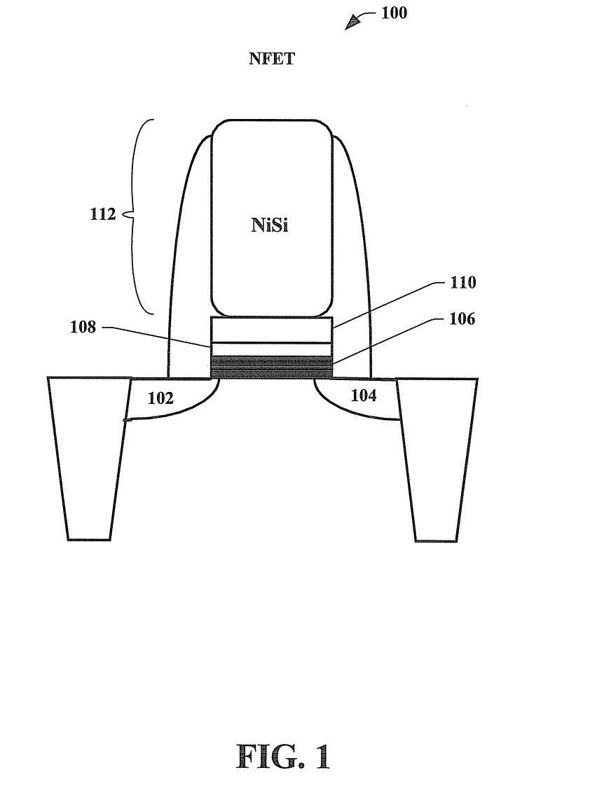

Now turning to the Figures, FIG. 1 illustrates a cross-sectional view of a semiconductor device structure 100. Such semiconductor device structure 100 can reduce contact resistance at NiSi/TiN with an nMOS compared to doped poly-Si/TiN interface. The semiconductor device structure (e.g., device) 100 is illustrated that can include a substrate and an n-channel MIS transistor. The n-channel MIS transistor can include a p-type semiconductor region formed on the substrate and a first source region 102 and a first drain region 104, wherein the first source/drain regions are formed in the p-type semiconductor region and being separated from each other. The n-channel MIS transistor can further include a first gate insulating film on the p-type semiconductor region between the first source/drain region. The n-channel MIS transistor can further include a first gate electrode having a stack formed with a gate dielectric 106, a first metal layer 108, and a first compound layer 110. The gate dielectric 106 is the gate dielectric can be any material with a high dielectric constant. The gate dielectric can be hafnium dioxide or a metal-silicon material. Metal-silicon-oxide materials included compositions having the following chemical formulae: MSiO, MSiON, M₁M₂SiO, MₓSi₁−xO₂, MₓSi₁₋ₓO₂, and MₓSi₁₋ₓON, wherein M and M₁ are independently an element of Group IVA or an element from the Lanthanide Series; M₂ is nitrogen, an element of Group IVA, or an element from the Lanthanide Series; and x is less than 1 and greater than 0. Specific examples include HfₓSi₁₋ₓO₂, HfₓSi₁₋ₓON, ZrₓSi₁₋ₓO₂, ZrₓSi₁₋ₓON, LaₓSi₁₋ₓO₂, LaₓSi₁₋ₓON, GdₓSi₁₋ₓO₂, GdₓSi₁₋ₓON, HfZrSiO, HfZrSiON, HfLaSiO, and HfGdSiO, where x is between 0 and 1. In one embodiment, the thickness of the gate dielectric layer 106 is from about 0.1 nm to about 25 nm. The metallic layer 108 can have a thickness less than 2 nm and a work function of 4.3 eV or smaller, wherein the first compound layer 110 being formed on the metallic layer 108 has a work function larger than 4.4 eV and the first compound layer 110 contains Al and a second metal that is different from the first metal. In general, the first metal layer 108 can be a metallic Al pile-up layer, the first compound layer 110 can be TiN or metals having a work function greater than 4.4 eV. Moreover, the first metallic layer 108 can be at least one of a metal or alloy selected from at least one of Al, In, TiAl, and TiIn. The device 100 can further include a region 112 that includes NiSi which can have an Al concentration (x) in NFET in NiSi layer as 1e17 cm−3<x<3e21 cm−3. The atomic ratio of Ni to Ni+Si in NiSi layer 112 is in the range of 0.3<Ni/(Ni+Si)<0.7. In this range, Al enough to modulate Vt can be piled-up at the gate dielectric interface. The first compound layer's thickness can be between 1 nm to 30 nm. Moreover, the first compound layer 110 can be at least one of a metal or an alloy selected from at least one of TiN, TiAlN, TiC, TaC, TaN, TaAlC, TaAlN, Ru, Re, or Ir. In addition, the contained metal in the first compound layer 110 and NiSi layer 112 are changed depending on metallic spices of metallic layer 108. The same metallic spices of 108 is included the first compound layer 110 and NiSi layer 112. In the following description, thought Al pile-up layer is used as the metallic layer which contact to gate dielectric in nMOS, another metal spices and alloys are also can be used substantially similar to FIG. 1.

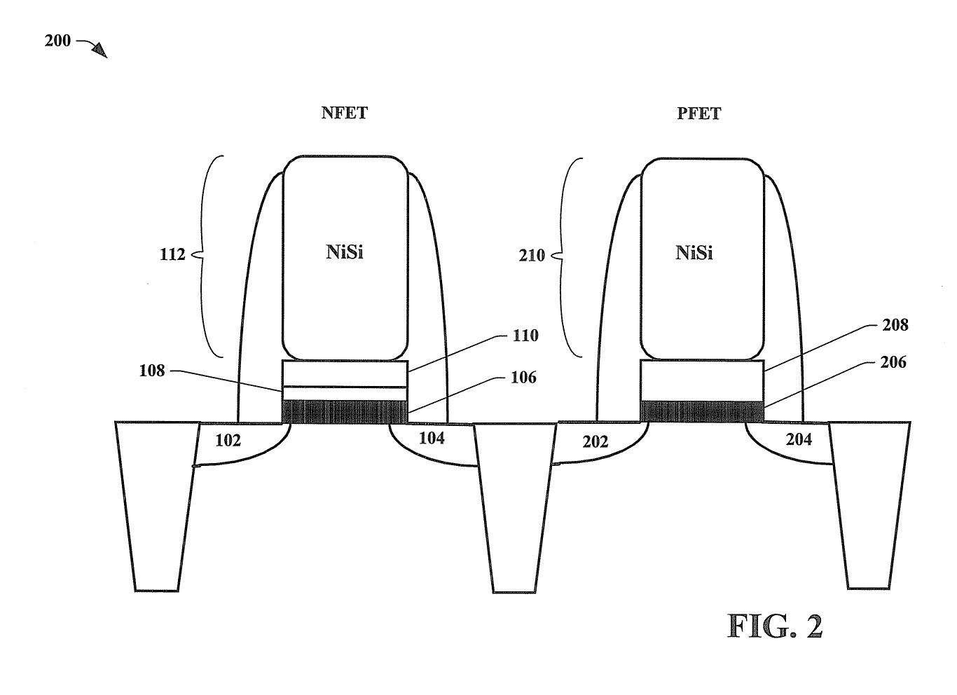

FIG. 2 illustrates a cross-sectional view of a semiconductor device structure 200. The semiconductor device structure (e.g., device) 200 can reduce contact resistance at NiSi and TiN with a CMOS. The device 200 can include a substrate and an n-channel MIS transistor. The n-channel MIS transistor can include a p-type semiconductor region formed on the substrate and a first source region 102 and a first drain region 104, wherein the first source/drain regions are formed in the p-type semiconductor region and being separated from each other. The n-channel MIS transistor can further include a first gate insulating film on the p-type semiconductor region between the first source/drain region. The n-channel MIS transistor can further include a first gate electrode having a stack formed with a gate dielectric 106, a first metal layer 108, and a first compound layer 110. The gate dielectric 106 is the gate dielectric can be any material with a high dielectric constant. The gate dielectric can be hafnium dioxide or a metal-silicon material. Metal-silicon-oxide materials included compositions having the following chemical formulae: MSiO, MSiON, M₁M₂SiO, MₓSi₁₋ₓO₂, MₓSi₁₋ₓO₂, and MₓSi₁₋ₓON, wherein M and M₁ are independently an element of Group IVA or an element from the Lanthanide Series; M₂ is nitrogen, an element of Group IVA, or an element from the Lanthanide Series; and x is less than 1 and greater than 0. Specific examples include HfₓSi₁₋ₓO₂, HfₓSi₁₋ₓON, ZrₓSi₁₋ₓO₂, ZrₓSi₁₋ₓON, LaₓSi₁₋ₓO₂, LaₓSi₁₋ₓON, GdₓSi₁₋ₓO₂, GdₓSi₁₋ₓON, HfZrSiO, HfZrSiON, HfLaSiO, and HfGdSiO, where x is between 0 and 1. In one embodiment, the thickness of the gate dielectric layer 106 is from about 0.1 nm to about 25 nm. The metallic layer 108 can have a thickness less than 2 nm and a work function of 4.3 eV or smaller, wherein the first compound layer 110 being formed on the metallic layer 108 has a work function larger than 4.4 eV and the first compound layer 110 contains Al and a second metal that is different from the first metal. The n-channel MIS transistor can further include a region 112 that includes NiSi which can have an Al concentration (x) in NFET in NiSi layer as 1e17 cm−3<x<3e21 cm−3. The atomic ratio of Ni to Ni+Si in NiSi layer 112 is in the range of 0.3<Ni/(Ni+Si)<0.7. In this range, Al enough to modulate Vt can be piled-up at the gate dielectric interface.

The device 200 can further include a p-type channel MIS transistor. The p-channel MIS transistor can include an n-type semiconductor that is formed on the substrate. The p-channel MIS transistor can further include a first source region 202 and a first drain region 204 that is formed in the n-type semiconductor region and separated from each other. The p-channel MIS transistor can further include a first gate insulating film on the n-type semiconductor region between the first source/drain region. Moreover, the p-channel MIS transistor can include a first gate electrode having a stack formed with a gate dielectric 206 and a first compound layer 208, wherein the first compound layer 208 can be formed on the gate dielectric 206 and having a work function larger than 4.4 eV. In general, the first compound layer 208 can be TiN or any suitable metal with a work function greater than 4.4 eV. The device 200 can further include a region 210 that includes NiSi. The first compound layer's thickness within the p-type channel MIS transistor region can be between 1 nm to 30 nm. Moreover, the first compound layer 208 within the p-type channel MIS transistor region can be at least one of a metal or an alloy selected from at least one of TiN, TiAlN, TiC, TaC, TaN, TaAlC, TaAlN, Ru, Re, or Ir. The p-channel MIS transistor can further include a region 210 that includes NiSi which can have an Al. In the case of the atomic ratio of Ni to Ni+Si in NiSi layer 210 is in the range of 0.3<Ni/(Ni+Si)<0.7 the first compound layer 208 is thicker than the first compound layer 110 in nFET or the Al diffusion coefficient in the first pFET compound layer 208 is lower than the first compound layer 110 in nFET to prevent Al piled-up layer formation. On the other hand, in the case of the atomic ratio of Ni to Ni+Si in NiSi layer 210 is larger than 0.7 (Ni/(Ni+Si)>0.7), the same thickness compound layer as nFET and the same Al diffusion coefficient layer can be also used for the first compound layer 208.

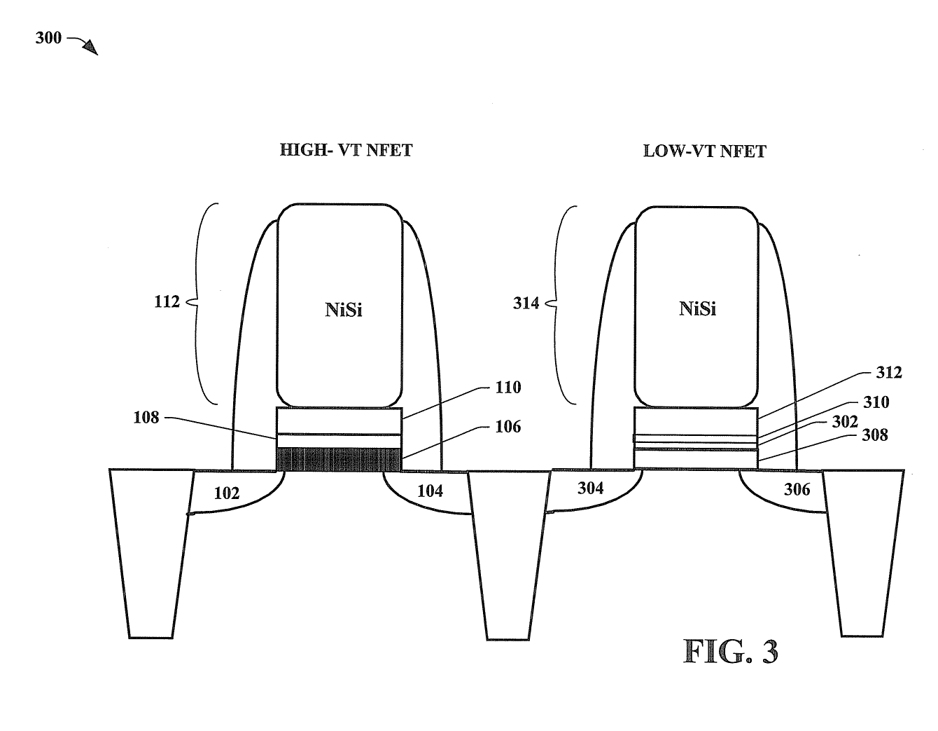

FIG. 3 illustrates a cross-sectional view of a semiconductor device structure 300. The semiconductor device structure (e.g., device) 300 can reduce contact resistance at NiSi and TiN with a high-Vt NFET and a low-Vt NFET. The device 300 can include a substrate and an n-channel MIS transistor with high-Vt, which can be substantially similar to the transistor structure in FIG. 1. The n-channel MIS transistor can include a p-type semiconductor region formed on the substrate and a first source region 102 and a first drain region 104, wherein the first source/drain regions are formed in the p-type semiconductor region and being separated from each other. The n-channel MIS transistor can further include a first gate insulating film on the p-type semiconductor region between the first source/drain region. The n-channel MIS transistor can further include a first gate electrode having a stack formed with a gate dielectric 106, a first metal layer 108, and a first compound layer 110. The gate dielectric 106 is the gate dielectric can be any material with a high dielectric constant. The gate dielectric can be hafnium dioxide or a metal-silicon material. Metal-silicon-oxide materials included compositions having the following chemical formulae: MSiO, MSiON, M₁M₂SiO, MₓSi₁₋ₓO₂, MₓSi₁₋ₓO₂, and MₓSi₁₋ₓON, wherein M and M₁ are independently an element of Group IVA or an element from the Lanthanide Series; M₂ is nitrogen, an element of Group IVA, or an element from the Lanthanide Series; and x is less than 1 and greater than 0. Specific examples include HfₓSi₁₋ₓO₂, HfₓSi₁₋ₓON, ZrₓSi₁₋ₓO₂, ZrₓSi₁₋ₓON, LaₓSi₁₋ₓO₂, LaₓSi₁₋ₓON, GdₓSi₁₋ₓO₂, GdₓSi₁₋ₓON, HfZrSiO, HfZrSiON, HfLaSiO, and HfGdSiO, where x is between 0 and 1. In one embodiment, the thickness of the gate dielectric layer 106 is from about 0.1 nm to about 25 nm. The metallic layer 108 can have a thickness less than 2 nm and a work function of 4.3 eV or smaller, wherein the first compound layer 110 being formed on the metallic layer 108 has a work function larger than 4.4 eV and the first compound layer 110 contains Al and a second metal that is different from the first metal and a IV-group semiconductor element. The device 300 can further include a region 112 that includes NiSi which can have an Al concentration (x) in NFET in NiSi layer as 1e17 cm−3<x<3e21 cm−3. The atomic ratio of Ni to Ni+Si in NiSi layer 112 is in the range of 0.3<Ni/(Ni+Si)<0.7. In this range, Al enough to modulate Vt can be piled-up at the gate dielectric interface.

The device 300 can further include a second n-channel MIS transistor with low-Vt that includes a p-type semiconductor region that is formed on the substrate and a first source region 304 and a first drain region 306 that is formed in the p-type semiconductor region that are separated from one another. The p-type semiconductor can further include a first gate insulating firm on the p-type semiconductor region between the first source/drain region. Moreover, the p-type semiconductor can include a first gate electrode having a stack structure formed with a gate dielectric 308, a first metal layer 310. The metallic layer 310 can have a thickness less than 2 nm and a work function of 4.3 eV or smaller, wherein the first compound layer 312 being formed on the metallic layer has a work function larger than 4.4 eV and the first compound layer 312 contains Al and a second metal that is different from the first metal. It is to be appreciated that the first gate electrode included within the low-Vt n-channel MIS transistor can be a rare-earth metal oxide-capped gate dielectric 302 between gate dielectric 308 and a first metal layer 310.

It is to be appreciated that the first compound layer's thickness included within the n-channel MIS transistor and the first compound layer's thickness included within the second n-channel MIS transistor can be between 1 nm and 30 nm. Additionally, the first compound layer 110 included within the n-channel MIS transistor and the first compound layer 312 included within the second n-channel MIS transistor can be at least one of a metal or an alloy selected from at least one of TiN, TiAlN, TiC, TaC, TaN, TaAlC, TaAlN, Ru, Re, or Ir. Furthermore, the Al concentration (x) in NFET in NiSi layer can be 1e17 cm−3<x<3e21 cm−3 while at the NiSi/TiN interface such concentration can be 1e20 cm−3<x. The atomic ratio of Ni to Ni+Si in NiSi layer 314 is in the range of 0.3<Ni/(Ni+Si)<0.7. In this range, Al enough to modulate Vt can be piled-up at the gate dielectric interface.

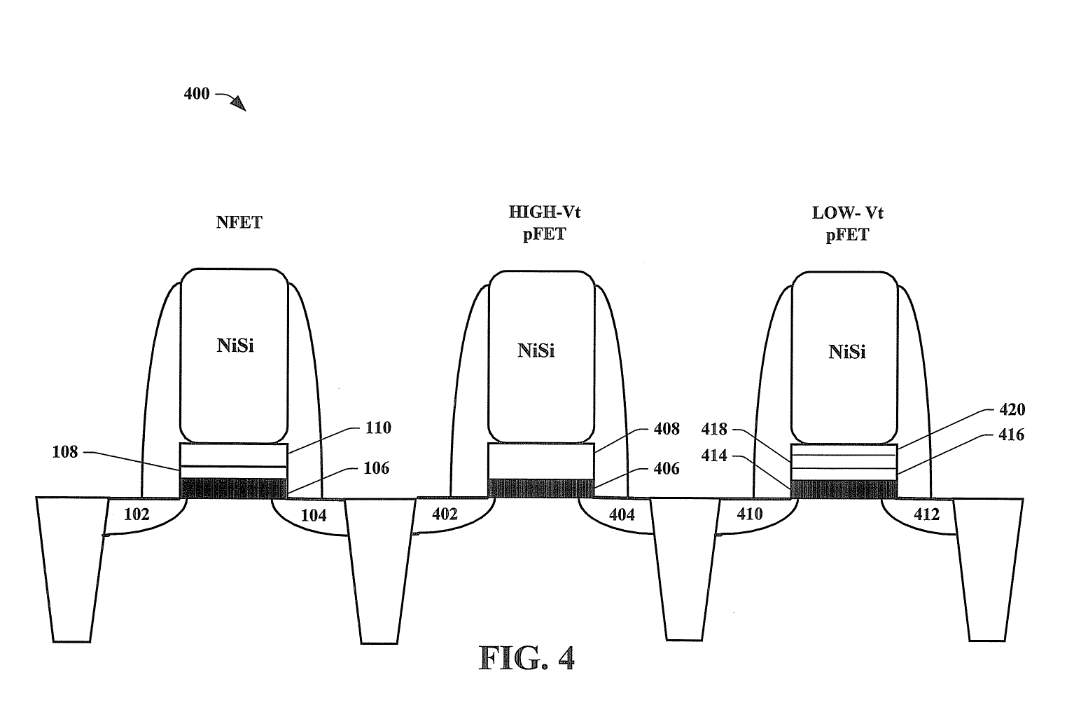

FIG. 4 illustrates a cross-sectional view of a semiconductor device structure 400. The semiconductor device structure 400 (e.g., device) can include 3 Vt (e.g., nMOS, midgap, and pMOS). The device 400 can further include a substrate and an n-channel MIS transistor region formed on the substrate, which can be substantially similar to the transistor structure in FIG. 1. The n-channel MIS transistor can include a p-type semiconductor region formed on the substrate, a first source region 102 and a first drain region 104 that is formed in the p-type semiconductor region and separated from one another, and a first gate insulating film on the p-type semiconductor region between the first source/drain region. The n-channel MIS transistor can further include a first gate electrode having a stack structure formed with a gate dielectric 106, a first metal layer 108, and a first compound layer 110. The gate dielectric 106 is the gate dielectric can be any material with a high dielectric constant. The gate dielectric can be hafnium dioxide or a metal-silicon material. Metal-silicon-oxide materials included compositions having the following chemical formulae: MSiO, MSiON, M₁M₂SiO, MₓSi₁₋ₓO₂, MₓSi₁₋ₓO₂, and MₓSi₁₋ₓON, wherein M and M₁ are independently an element of Group IVA or an element from the Lanthanide Series; M₂ is nitrogen, an element of Group IVA, or an element from the Lanthanide Series; and x is less than 1 and greater than 0. Specific examples include HfₓSi₁₋₁O₂, HfₓSi₁₋ₓON, ZrₓSi₁₋ₓO₂, ZrₓSi₁₋ₓON, LaₓSi₁₋ₓO₂, LaₓSi₁₋ₓON, GdₓSi₁₋ₓO₂, GdₓSi₁₋ₓON, HfZrSiO, HfZrSiON, HfLaSiO, and HfGdSiO, where x is between 0 and 1. In one embodiment, the thickness of the gate dielectric layer 106 is from about 0.1 nm to about 25 nm. The metallic layer 108 can have a thickness less than 2 nm and a work function of 4.3 eV or smaller. The first compound layer 110 can be formed on the metallic layer 108 and have a work function larger than 4.4 eV and the first compound layer 110 can contain Al and a second metal that is different from the first metal.

The device 400 can include a first p-type channel MIS transistor (HighVt-PFET) that can include an n-type semiconductor region that is formed on the substrate, a first source region 402 and a first drain region 404 that are formed in the n-type semiconductor region and separated from one another, and a first gate insulating film on the n-type semiconductor region between the source/drain region. The first p-type channel MIS transistor can further include a first gate electrode having a stack structure formed with a gate dielectric 406 and a first metal layer 408. It is to be appreciated that the first metal layer 408 included within the first p-type channel MIS transistor is a Si midgap work function or larger than Si midgap work function, wherein the work function can be greater than 4.4 eV. Moreover, the midgap work function or larger than Si midgap work function metal can be at least one of a metal or an alloy selected from at least one of TiN, TiAlN, TiC, TaC, TaN, TaAlC, TaAlN, Ru, Re, or Ir.

Furthermore, the device 400 can include a second p-channel MIS transistor (low-Vt PFET) that includes an n-type semiconductor region formed on the substrate, a first source region 410 and a first drain region 412 that are formed in the n-type semiconductor region and separated from each other, and a first gate insulating film on the n-type semiconductor region between the first source/drain region. The second p-channel MIS transistor can further include a first gate electrode that has a stack structure that can be formed with an oxidized layer 416 contact gate dielectric 414, a first compound layer 418, and a metallic Al layer 420. The oxidized layer 416 can be formed on the gate dielectric with a thickness less than 2 nm. The first compound layer 418 can be formed on the oxidized Al layer 416 with a work function larger than 4.4 eV, whereas the first compound layer 418 can contain Al and a second metal that differs from the first metal.

The oxidized layer 416 can be an Al oxide layer. The first compound layer's thickness included within the n-channel MIS transistor and the first compound layer's thickness included within the second p-channel MIS transistor can be between 1 nm to 30 nm. The first compound 110 within the n-type channel MIS transistor and the first compound layer 418 included within the second p-type channel MIS transistor is at least one of a metal or an alloy selected from at least one of TiN, TiAlN, TiC, TaC, TaN, TaAlC, TaAlN, Ru, Re, or Ir. In the case of the atomic ratio of Ni to Ni+Si in NiSi layer is in the range of 0.3<Ni/(Ni+Si)<0.7 the first compound layer in high-Vt pFET 408 is thicker than the first compound layer 110 in nFET, or the Al diffusion coefficient in the high-Vt PFET compound layer 408 is lower than the first compound layer 110 in nFET to prevent Al piled-up layer formation. On the other hand, in the case of the atomic ratio of Ni to Ni+Si in NiSi layer is larger than 0.7 (Ni/(Ni+Si)>0.7) in the High-Vt PFET, the same thickness compound layer as nFET and the same Al diffusion coefficient layer can be also used for the first compound layer 408. These three metal gate electrode have NiSi top layer which contained Al concentration (x) as 1e17 cm−3<x<3e21 cm−3.

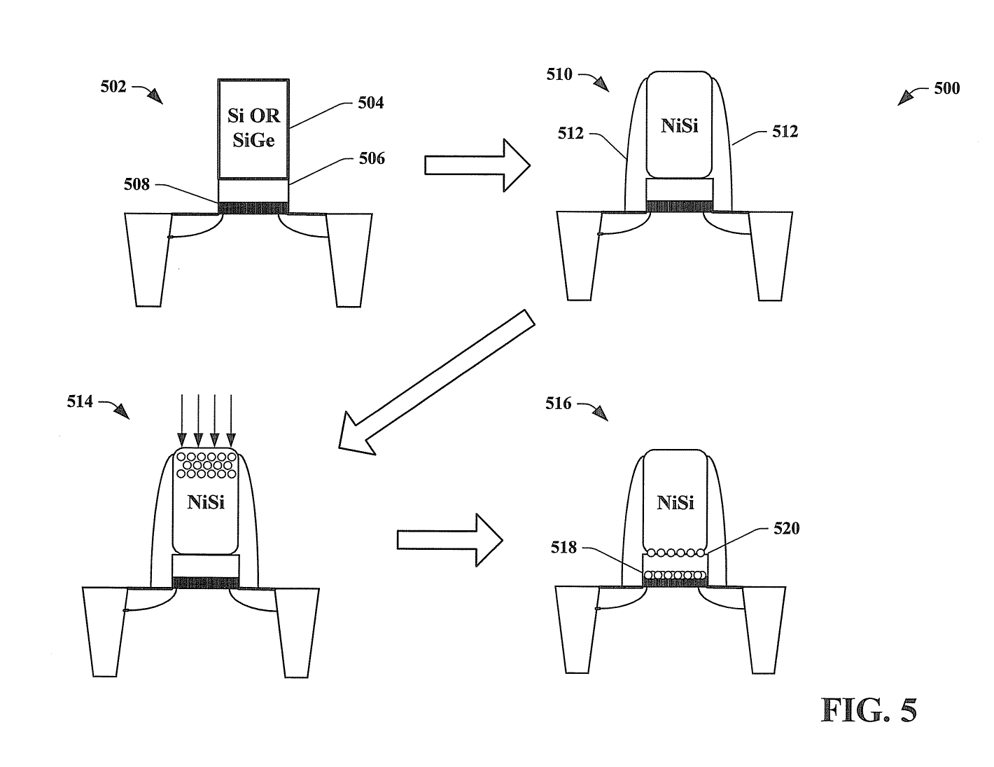

Referring now to FIG. 5, a method for manufacturing the semiconductor device in accordance with an aspect of the subject innovation is described. FIG. 5 illustrates a methodology 500 with schematic views illustrating the procedures for forming a nMISFET in accordance with an aspect of the invention. At cross-sectional view 502, film deposit is implemented for Si (e.g., SiGe, etc.) 504, TiN (e.g., metal or alloy as previously described, etc.) 506, and/or a gate dielectric 508. Moreover, a gate Reactive Ion Etching (gate-RIE) can be employed as well as a source and drain region I/I. At cross-sectional view 510, a gate-sidewall 512 can be formed as well as a Ni silicide formation on top of the poly-Si layer by a FUSI process. At cross-sectional view 514, Al ion implantation can be employed to the NiSi gate, wherein such ion implantation can be a dose greater than 1e15cm−2. At cross-sectional view 516, Al diffusion anneal can be performed. The temperature range of Al diffusion anneal can be in the range between 250° C. and 650° C. At 518, an Al pile-up layer can be created that is less than 2 nm. At 520, Al can be included at the NiSi/TiN interface which can decrease Rc owing to reducing of oxide layer at NiSi/TiN.

With respect to any figure or numerical range for a given characteristic, a figure or a parameter from one range may be combined with another figure or a parameter from a different range for the same characteristic to generate a numerical range.

While the invention has been explained in relation to certain aspects, it is to be understood that various modifications thereof will become apparent to those skilled in the art upon reading the specification. Therefore, it is to be understood that the innovation disclosed herein is intended to cover such modifications as fall within the scope of the appended claims.

What is claimed is:

1. A semiconductor device, comprising:
a substrate;
an n-channel MIS transistor including:
a p-type semiconductor region formed on the substrate;
a first source/drain region being formed in the p-type semiconductor region and being separated from each other;
a first gate insulating film on the p-type semiconductor region between the first source/drain region; and
a first gate electrode having a stack structure formed with a gate dielectric, a first metal layer and a first compound layer, the first metal layer having a thickness less than 2 nm and having a work function of 4.3 eV or smaller, the first compound layer being formed on the first metal layer having a work function larger than 4.4 eV and the first compound layer containing Al and a second metal that is different from the first.

2. The semiconductor device according to claim 1, wherein the first compound layer's thickness is between 1 nm to 30 nm.

3. The semiconductor device according to claim 1, wherein the first compound layer is at least one of a metal or an alloy selected from at least one of TiN, TiAlN, TiC, TaC, TaN, TaAlC, TaAlN, Ru, Re, or Ir.

4. The semiconductor device according to claim 1, wherein the first metal layer is selected from at least one of Al, In, TiAl, or TiIn.

5. The semiconductor device according to claim 1, further comprising:
a p-type channel MIS transistor including:
an n-type semiconductor region formed on the substrate;
a first source/drain region being formed in the n-type semiconductor region and being separated from each other;
a first gate insulating film on the n-type semiconductor region between the first source/drain region; and
a first gate electrode having a stack structure formed with a gate dielectric and a first compound layer, the first compound layer being formed on the metallic layer having a work function larger than 4.4 eV.

6. The semiconductor device according to claim 5, wherein the first compound layer's thickness within the p-type channel MIS transistor region is between 1 nm to 30 nm.

7. The semiconductor device according to claim 5, wherein the first compound layer within the p-type channel MIS transistor region is at least one of a metal or an alloy selected from at least one of TiN, TiAlN, TiC, TaC, TaN, TaAlC, TaAlN, Ru, Re, or Ir.

8. The semiconductor device according to claim 1, further comprising:
the first gate electrode included within the n-channel MIS transistor is a rare-earth metal oxide-capped gate dielectric;
a second n-channel MIS transistor including:
a p-type semiconductor region formed on the substrate;
a first source/drain region being formed in the p-type semiconductor region and being separated from each other;
a first gate insulating film on the p-type semiconductor region between the first source/drain region; and
a first gate electrode having a stack structure formed with a gate dielectric, a first metal layer and a first compound layer, the first metal layer having a thickness less than 2 nm and having a work function of 4.3 eV or smaller, the first compound layer being formed on the metallic layer having a work function larger than 4.4 eV and the first compound layer containing Al and a second metal that is different from the first metal.

9. The semiconductor device according to claim 8, wherein the first compound layer's thickness included within the n-channel MIS transistor and the first compound layer's thickness included within the second n-channel MIS transistor is between 1 nm to 30 nm.

10. The semiconductor device according to claim 8, wherein the first compound layer included within the n-channel MIS transistor and the first metal layer included within the second n-channel MIS transistor is at least one of a metal or an alloy selected from at least one of TiN, TiAlN, TiC, TaC, TaN, TaAlC, TaAlN, Ru, Re, or Ir.

11. The semiconductor device according to claim 8, wherein the first metal layer is selected from at least one of Al, In, TiAl, or TiIn.

12. A semiconductor device, comprising:
a substrate;
an n-channel MIS transistor including:
a p-type semiconductor region formed on the substrate;
a first source/drain region being formed in the p-type semiconductor region and being separated from each other;
a first gate insulating film on the p-type semiconductor region between the first source/drain region; and
a first gate electrode having a stack structure formed with a gate dielectric, a first metal layer and a first compound layer, the first metal layer having a thickness less than 2 nm and having a work function of 4.3 eV or smaller, the first compound layer being formed on the first metal layer having a work function larger than 4.4 eV and the first compound layer containing Al and a second metal that is different from the first;
a first p-type channel MIS transistor region including:
an n-type semiconductor region formed on the substrate;
a first source/drain region being formed in the n-type semiconductor region and being separated from each other;
a first gate insulating film on the n-type semiconductor region between the first source/drain region;
a first gate electrode having a stack structure formed with a gate dielectric and a first compound layer, the first compound layer being formed on the metallic layer having a work function larger than 4.4 eV; and
a second p-type channel MIS transistor region including:
an n-type semiconductor region formed on the substrate;
a first source/drain region being formed in the n-type semiconductor region and being separated from each other;
a first gate insulating film on the n-type semiconductor region between the first source/drain region;
a first gate electrode having a stack structure formed with an oxidized layer contact gate dielectric, a first metal layer, a first compound layer, and a metallic Al layer, the oxidized layer being formed on the gate dielectric with a thickness less than 2 nm, the first metal layer having a thickness less than 2 nm and having a work function of 4.3 eV or smaller, the first metal layer being formed on the compound layer having a work function larger than 4.4 eV and the first compound layer containing Al and a second metal that is different from the first metal.

13. The semiconductor device according to claim 12, the oxidized layer is an Al oxide layer.

14. The semiconductor device according to claim 12, the first compound layer included within the first p-type channel MIS transistor is a Si midgap work function metal or higher than that, wherein the work function is greater than 4.4 eV.

15. The semiconductor device according to claim 14, the Si midgap work function metal or higher than that is at least one of a metal or an alloy selected from at least one of TiN, TiAlN, TiC, TaC, TaN, TaAlC, TaAlN, Ru, Re, or Ir.

16. The semiconductor device according to claim 12, wherein the first compound layer's thickness included within the n-type channel MIS transistor and the first compound layer's thickness included within the second p-type channel MIS transistor is between 1 nm to 30 nm.

17. The semiconductor device according to claim 12, wherein the first metal layer included within the n-type channel MIS transistor and the first metal layer included within the second p-type channel MIS transistor is at least one of a metal or an alloy selected from at least one of TiN, TiAlN, TiC, TaC, TaN, TaAlC, TaAlN, Ru, Re, or Ir.

18. The semiconductor device according to claim 12, wherein the first metal included within the n-type channel MIS transistor and the second metal included within the second p-type channel MIS transistor is selected from at least one of Al, In, TiAl, or TiIn.

19. A method for manufacturing a semiconductor device, comprising:
forming a p-type semiconductor region on a substrate;
forming a first source/drain region in the p-type semiconductor region and being separated from each other;
forming a first gate insulating film on a p-type semiconductor region between the first source/drain;
forming a first gate electrode stack structure with, a first metal layer and a first compound layer, the first metal layer having a thickness less than 2 nm and having a work function of 4.3 eV or smaller, the first compound layer being formed on the metallic layer having a work function larger than 4.4 eV and the first compound layer containing Al and a second metal that is different from the first metal.

20. The method for manufacturing the semiconductor device according to claim 19, further comprising:
utilizing film deposit for an IV-group semiconductor region and the first compound layer;
performing Reactive Ion Etching (RIE) to form the first gate;
forming a gate side-wall and Ni Silicide on top of a poly-Si layer with a fully silicided (FUSI) process;
performing Al ion implantation to top of NiSi gate; and
performing Al diffusion anneal.
